(19) United States
(12) Patent Application Publication
(10) Pub. No.: US 2025/0210399 A1
(43) Pub. Date: Jun. 26, 2025

(54) MICRO-TRANSFER PRINTING METHODS

(71) Applicant: X-Celeprint Limited, Dublin (IE)

(72) Inventors: Ronald S. Cok, Rochester, NY (US); David Gomez, Holly Springs, NC (US); Prasanna Ramaswamy, Cork (IE)

(21) Appl. No.: 18/390,483

(22) Filed: Dec. 20, 2023

(51) Int. Cl. H01L 21/683; H01L 21/687

(52) U.S. Cl. CPC H01L 21/6835; H01L 21/68764; H01L 2221/68318; H01L 2221/68368

(57) ABSTRACT

A method of micro-transfer printing includes providing a stamp controlled by a motion-control platform and a micro-component source wafer comprising a micro-component disposed over a cavity in a surface of the micro-component source wafer and connected to the micro-component source wafer with a tether. The stamp can contact the micro-component to adhere the micro-component to the stamp. The stamp and the micro-component can be removed from the micro-component source wafer by moving the stamp in a vertical direction orthogonal to the surface and in a horizontal direction parallel to the surface.

### TECHNICAL FIELD This disclosure relates generally to micro-transfer printing methods using an elastomeric stamp.

### BACKGROUND

Substrates with electronically active components distributed over the extent of the substrate are used in a variety of electronic systems, for example, in flat-panel display components such as flat-panel liquid crystal or organic light emitting diode (OLED) displays, in imaging sensors, and in flat-panel solar cells. The electronically active components are typically either assembled on the substrate, for example using individually packaged surface-mount integrated-circuit components and pick-and-place tools, or by coating a layer of semiconductor material on the substrate and then photolithographically processing the semiconductor material to form thin-film circuits on the substrate. Individually packaged integrated-circuit components typically have smaller transistors with higher performance than thin-film circuits but the packages are larger than can be desired for highly integrated systems.

Methods for transferring small, active components from one substrate to another are described in U.S. Pat. Nos. 7,943,491, 8,039,847, and 7,622,367. In some such approaches, small integrated circuits are formed on a native semiconductor source wafer. The small, unpackaged integrated circuits, or chiplets, are released from their native source wafer by pattern-wise etching portions of a sacrificial layer located beneath the chiplets, leaving each chiplet suspended over an etched sacrificial layer portion by a tether physically connecting the chiplet to an anchor separating the etched sacrificial layer portions. A viscoelastic stamp is pressed against the process side of the chiplets on the native source wafer, adhering each chiplet to an individual stamp post. The stamp with the adhered chiplets is removed from the native source wafer. The chiplets on the stamp posts are then pressed against a non-native target substrate or backplane with the stamp and adhered to the target substrate.

In another example, U.S. Pat. No. 8,722,458 entitled Optical Systems Fabricated by Printing-Based Assembly teaches transferring light-emitting, light-sensing, or light-collecting semiconductor elements from a source wafer substrate to a destination substrate or backplane. Such micro-transferred components can provide the high performance of crystalline semiconductor components together with the small size of unpackaged dies.

Micro-transfer printing stamps are an important part of any micro-transfer printing system and method. Typically, each stamp comprises an array of individual stamp posts and each stamp post contacts a chiplet during printing. The structure of the stamp post can affect the chiplet pickup from a source wafer and the chiplet printing to a target substrate. In some designs, the distal end of each individual stamp post is flat. In other designs, the distal end of each individual stamp post is structured. For example, U.S. Pat. No. 9,412,727 discloses a stamp with micro-tips in a three-dimensional relief pattern. There is an ongoing need, therefore, for stamp structures that are highly reliable, provide excellent pick-up-and-print yields, and are easy-to-use for a variety of component micro-transfer printing processes.

### SUMMARY

The present disclosure provides, inter alia, devices, structures, systems, and construction methods for micro-assembling micro-components, such as micro-electronic components, micro-optical components, silicon components, and compound semiconductor components using a stamp-based micro-transfer printing process. Such micro-assembled micro-components and systems and structures comprising them are widely useful in electronic and photonic systems.

According to embodiments of the present disclosure, a method of micro-transfer printing can comprise providing a stamp (e.g., a visco-elastic stamp comprising PDMS), providing a micro-component source wafer comprising a micro-component disposed over a cavity in a surface of the micro-component source wafer and connected to the micro-component source wafer with a tether, contacting the stamp to the micro-component to adhere the micro-component to the stamp, and detaching the micro-component from the micro-component source wafer by moving the stamp at least in a horizontal direction parallel to the surface, and optionally in a vertical direction orthogonal to the surface (e.g., orthogonal to the horizontal direction), thereby fracturing or separating the tether. Detaching the micro-component from the anchor and from the micro-component source wafer can comprise fracturing (e.g., breaking) the tether or separating the tether from the micro-component or from the anchor and micro-component source wafer. Once detached (e.g., the tether is fractured or separated), the micro-component can be removed from the micro-component source wafer using any combination of vertical and horizontal movements of the stamp. The stamp can be controlled by a computer-controlled motion-control platform with optical or mechanical (or both) alignment capabilities.

Some embodiments comprise also moving the stamp in a vertical direction orthogonal to the surface to detach the micro-component from the anchor and micro-component source wafer. Some embodiments comprise moving the stamp in the vertical direction at the same time as moving the stamp in the horizontal direction. Some embodiments comprise moving the stamp in the vertical direction after moving the stamp in the horizontal direction.

In some embodiments, a movement of the stamp in the vertical direction to detach the micro-component is a movement toward the surface. In some embodiments, a movement of the stamp in the vertical direction to detach the micro-component is a movement toward the surface. In some embodiments, the movement of the stamp in the vertical direction to detach the micro-component is an alternation in movements toward and away from the surface (e.g., an oscillation or vibration).

In some embodiments, a movement of the stamp in the horizontal direction comprises a rotation of the stamp about a vertical axis extending in the vertical direction orthogonal to the surface and orthogonal to the horizontal direction.

In some embodiments, the tether extends horizontally in a horizontal tether direction away from an anchor portion of the micro-component source wafer toward the micro-component and moving the stamp comprises moving the stamp in the horizontal direction parallel to the surface and in the tether direction to stretch the tether. In some embodiments, the tether extends horizontally in a horizontal tether direction away from an anchor portion of the micro-component source wafer toward the micro-component and the horizontal direction parallel to the surface is orthogonal to the tether direction. Moving the stamp in the horizontal direction can comprise moving the stamp parallel to the surface and orthogonal to the tether direction. In some embodiments, the tether extends in a tether direction away from an anchor portion of the micro-component source wafer toward the micro-component and the direction parallel to the micro-component source wafer is orthogonal to the tether direction and moving the stamp comprises a rotation about a vertical axis extending in the vertical direction orthogonal to the surface that stretches (places under tension) a leading edge of the tether moving in the orthogonal direction and compresses the trailing edge of the tether.

In some embodiments, the horizontal direction is a combination of a rotation about a vertical axis extending in the vertical direction orthogonal to the surface and a translation (e.g., movement) of the micro-component over the surface in a horizontal direction.

In some embodiments of the present disclosure, the tether extends laterally from an edge of the micro-component to an anchor portion of the micro-component source wafer. In some embodiments of the present disclosure, the tether extends from a bottom of the micro-component to the micro-component source wafer.

In some embodiments, the stamp comprises a rigid back, a stamp post extends away from the rigid substrate, and a distal end of the stamp post contacts the micro-component. In some embodiments, the stamp comprises a pedestal disposed on the rigid substrate and a proximal end of the post is in contact with the pedestal or bulk layer.

According to embodiments of the present disclosure, a structure for micro-transfer printing can comprise a micro-component source wafer comprising a micro-component disposed over a cavity in a surface of the micro-component source wafer and connected to an anchor portion of the micro-component source wafer with a tether that extends from the anchor to the micro-component, and a stamp disposed in contact with the micro-component that adheres the micro-component to the stamp. The stamp provides force to (e.g., provides pressure to or pushes or pulls) the micro-component in a horizontal direction parallel to the surface. In some embodiments, the stamp also provides force to (e.g., provides pressure to or pushes or pulls) the micro-component in a vertical direction orthogonal to the surface.

In some embodiments, the force provided by the stamp places at least a portion of the tether under tension in the horizontal direction. In some embodiments, the force in the horizontal direction is a rotation. The force in the horizontal direction can be in a direction in which the tether extends from the anchor to the micro-component. The force in the horizontal direction can be orthogonal to a direction from the anchor to the micro-component. The force in the horizontal direction can be in a direction from the anchor to the micro-component and orthogonal to a direction from the anchor to the micro-component. The force in the horizontal direction can be one or more or any combination of (i) a force in a direction orthogonal to a direction from the anchor to the micro-component, (ii) a force in a direction from the anchor to the micro-component, and (iii) a rotational force about a vertical axis extending in the vertical direction.

According to embodiments of the present disclosure, a method of micro-transfer printing comprises providing a micro-component source wafer comprising a micro-component disposed over a cavity in a surface of the micro-component source wafer and connected to the micro-component source wafer and detaching the micro-component from the micro-component source wafer by moving the micro-component at least in a horizontal direction parallel to the surface. In embodiments, the micro-component is connected to the micro component source wafer with a tether and detaching the micro-component from the micro-component source wafer fractures or separates the tether.

Embodiments of the present disclosure provide improvements in picking printing micro-components from micro-component source wafers to micro-transfer print the micro-components.

### BRIEF DESCRIPTION OF THE DRAWINGS

Drawings are presented herein for illustration purposes, not for limitation. Drawings are not necessarily drawn to scale. The foregoing and other objects, aspects, features, and advantages of the disclosure will become more apparent and may be better understood by referring to the following description taken in conjunction with the accompanying drawings, in which:

FIG. 1 is a perspective of a printable micro-component and micro-component source wafer according to illustrative embodiments of the present disclosure;

FIG. 2 is a perspective of a printable micro-component and micro-component source wafer as shown in FIG. 1 together with a printing stamp showing stamp movement in horizontal and vertical directions according to illustrative embodiments of the present disclosure;

FIG. 3A is a cross section of a released micro-component with a lateral tether and a printing stamp corresponding to FIG. 2 according to illustrative embodiments of the present disclosure;

FIG. 3B is a cross section of a released micro-component with a bottom tether and a printing stamp according to illustrative embodiments of the present disclosure;

FIG. 4A is a cross section of a micro-component with a lateral tether and a top-view detail of the lateral tether together with a stamp moving the micro-component in a vertical direction away from the micro-component source wafer according to illustrative embodiments of the present disclosure;

FIG. 4B is a cross section of a micro-component with a lateral tether and a top-view detail of the tether together with a stamp moving the micro-component in a vertical direction toward the micro-component source wafer according to illustrative embodiments of the present disclosure;

FIG. 5 is a plan (top) view of a micro-component with a lateral tether connected to an anchor and a stamp moving the micro-component in a horizontal direction away from the anchor according to illustrative embodiments of the present disclosure;

FIG. 6 is a plan (top) view of a micro-component with a lateral tether connected to an anchor and a stamp moving the micro-component in a horizontal direction orthogonal to a direction from the anchor toward the micro-component according to illustrative embodiments of the present disclosure;

FIG. 7 is a plan (top) view of a micro-component with a lateral tether connected to an anchor and a stamp rotating the micro-component in a horizontal direction according to illustrative embodiments of the present disclosure;

FIG. 8 is plan (top) view of a micro-component with a lateral tether connected to an anchor and a stamp moving the micro-component in three horizontal directions according to illustrative embodiments of the present disclosure;

FIGS. 9A-9C are plan (top) views of a crack propagating in a tether according to illustrative embodiments of the present disclosure; and

FIG. 10 is a flow diagram of methods according to illustrative embodiments of the present disclosure.

### DETAILED DESCRIPTION OF CERTAIN EMBODIMENTS

Certain embodiments of the present disclosure provide, inter alia, devices, structures, systems, and construction methods for micro-assembling micro-components, such as micro-electronic components, micro-optical components, micro-photonic components, micro-silicon components, and micro-compound semiconductor components using a stamp-based micro-transfer printing process. Such micro-assembled micro-components and systems and structures comprising them are widely useful in electronic and photonic systems.

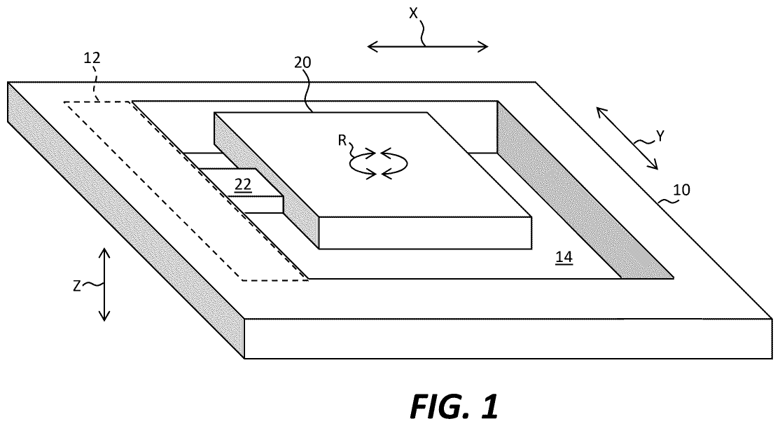

According to embodiments of the present disclosure and as illustrated in FIGS. 1, 2, 3A, and 3B, a micro-component 20 can be physically connected to an anchor 12 of a micro-component source wafer 10 with a tether 22. As used herein, anchor 12 of micro-component source wafer 10 is an anchor portion of micro-component source wafer 10 and the terms anchor 12 and anchor portion 12 are used interchangeably. Anchor 12 can be a portion of or an additional structure disposed on micro-component source wafer 10. Micro-component 20 and tether 22 can be released from micro-component source wafer 10 by under-etching micro-component 20 and tether 22, for example by etching a release layer disposed beneath micro-component 20 and tether 22 to suspend micro-component 20 with tether 22 over a surface 16 of micro-component source wafer 10 and directly above a cavity 14 in micro-component source wafer 10.

Micro-component source wafer 10 can be any substrate or wafer on which the structure of FIG. 1 can be constructed, for example a semiconductor substrate such as silicon or a compound semiconductor substrate. The semiconductor substrate can have a release layer, for example an insulator layer found in a semiconductor-on-insulator (SOI) wafer or the semiconductor material beneath micro-component 20 anisotropically etched to form cavity 14. Anchor 12 can be any portion (e.g., an anchor portion) of micro-component source wafer 10 to which tether 22 is attached that is not removed during the release layer etch. Tether 22 can be any patterned material that connects micro-component 20 to anchor 12, including an organic dielectric such as a photoresist or cured adhesive, an inorganic dielectric such as a SiO₂ or SiN, a semiconductor material such as a material comprising micro-component source wafer 10, or any combination of these. Micro-component 20 can be any useful structure formed on or in micro-component source wafer 10, such as an integrated circuit, a photonic circuit, a passive electronic device, or a passive photonic device, and can be made using photolithographic methods and materials found in the integrated circuit and MEMs arts. Micro-component 20 can comprise a semiconductor material, such as silicon or a compound semiconductor such as GaN, InGaN, GaAs and the like, dielectric materials such as SiO2, SiN, photoresists or adhesives such as BCB (benzocyclobutene) or Intervia, and metals, for example patterned metals that conduct electrical signals. Micro-component 20, tether 22, and cavity 14 can be formed using photolithographic methods and materials, including MEMs methods and materials.

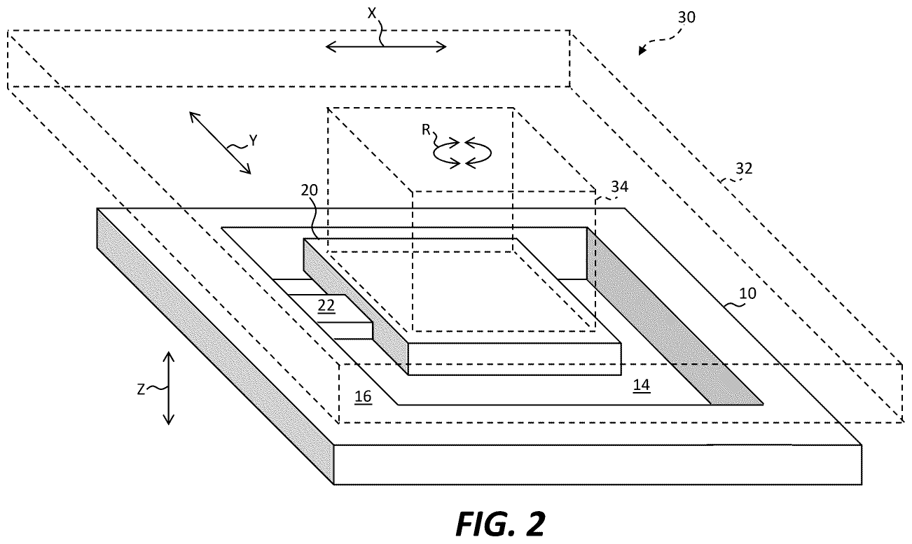

A shown in FIG. 2, micro-components 20 released from their native micro-component source wafer 10 substrates and suspended over cavity 14 in micro-component source wafer 10 with tether 22 can be micro-transfer printed to a target substrate (not shown) using an elastic, elastomeric, or visco-elastic stamp 30, such as PDMS (polydimethylsiloxane), by contacting stamp 30 to micro-component 20 to adhere micro-component 20 to stamp 30 and moving stamp 30 with respect to micro-component source wafer 10 to move micro-component 20, thereby fracturing or separating tether 22 and detaching micro-component 20 from micro-component source wafer 10, transporting stamp 30 with adhered micro-component 20 to a target substrate, contacting the adhered micro-component 20 to the target substrate, and removing stamp 30.

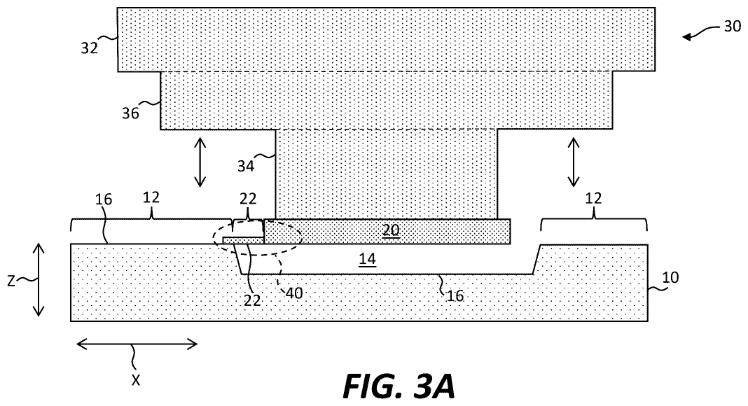

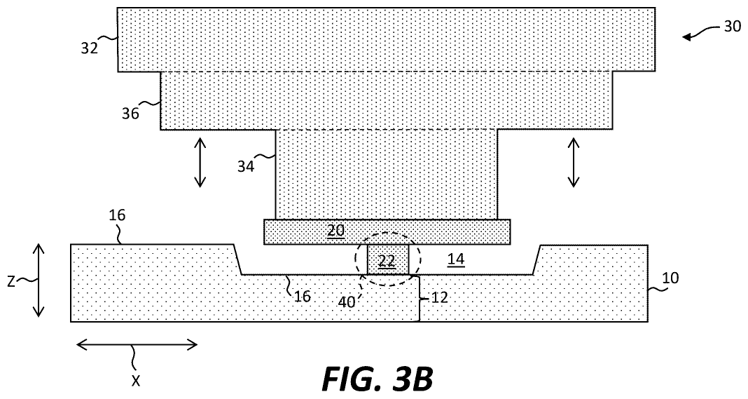

FIG. 2 shows micro-component 20 and micro-component source wafer 10 of FIG. 1 with the addition of stamp 30. Stamp 30 can comprise a glass rigid back 32 (for example a substrate made of glass), a stamp pedestal 36 or bulk material comprising PDMS disposed on rigid back 32, and a stamp post 34 comprising PDMS disposed on stamp pedestal 36 (or the bulk layer) and extending away from stamp pedestal 36 and rigid back 32, as shown in the cross section of FIG. 3A. (The bulk layer can be disposed on rigid back 32 and pedestal 36 can be disposed on the bulk layer.) For clarity, in FIG. 2 stamp pedestal 36 and any bulk layer is omitted and only rigid back 32 and stamp post 34 are shown with dashed lines. More generally (but not shown in the figures), stamp 30 can comprise rigid back 32, a bulk layer of PDMS disposed on rigid back 32, a pedestal 36 disposed on the bulk layer, and multiple stamp posts 34, each extending from stamp pedestal 36 and able to contact a separate micro-component 20, to micro-transfer print multiple micro-components 20 at a time in a single print step.

Stamp 30 can be controlled by a micro-transfer printer comprising a motion-control platform with optical alignment capabilities. As shown in FIGS. 1 and 2, the motion-control platform can move stamp 30 vertically in a direction Z (e.g., toward or away from micro-component source wafer 10) and horizontally (e.g., in a horizontal direction parallel to a surface of micro-component source wafer 10 over, on, or in which micro-component 20 is disposed). According to embodiments of the present disclosure, a horizontal direction is orthogonal to vertical direction Z and can be any one or combination of a horizontal direction X extending from anchor 12 to micro-component 20, a horizontal direction Y orthogonal to direction X, or a rotation direction R that rotates about an axis extending in direction Z. Directions X, Y, Z and R are each indicated with arrows in FIGS. 1 and 2. Directions X and Z are similarly indicated in FIGS. 3A and 3B. The directions indicated can be bidirectional in a corresponding dimension.

FIG. 3A illustrates stamp 30 picking up micro-component 20 by contacting micro-component 20 with stamp post 34 using a vertical motion in direction Z toward micro-component source wafer 10 to adhere micro-component 20 to stamp post 34 and then using a vertical motion in direction Z away from micro-component source wafer 10 to remove micro-component 20 from micro-component source wafer 10 and fracture (e.g., break) or separate tether 22 from micro-component 20 or micro-component source wafer 10. Before contacting micro-component 20 removal, tether 22 connects micro-component 20 to anchor 12, suspending contacting micro-component 20 over etched cavity 14 in micro-component source wafer 10. As shown in FIG. 3A, tether 22 extends laterally from micro-component 20 to anchor 12. A patterned material comprising tether 22 can extend over or under micro-component 20 (e.g., as an encapsulation, substrate, or epitaxial layer) and can also extend over anchor 12, forming a portion of anchor 12. In FIG. 3A, tether 22 comprises undercut material over cavity 14 that is not part of micro-component 20 and is typically patterned to preferentially fracture or separate when micro-component 20 is removed by stamp 30 from micro-component source wafer 10. Micro-component 20 can be attached to anchor(s) 12 with one (as shown) or multiple tethers 22 (not shown) when suspended over cavity 14.

FIG. 3B illustrates embodiments of the present disclosure in which tether 22 is a bottom tether 22 disposed under micro-component 20 between micro-component 20 and micro-component source wafer 10 that extends vertically from cavity 14 to micro-component 20. In such embodiments, micro-component 20 is undercut everywhere except for tether 22. As in FIG. 3A, stamp 30 can remove micro-component 20 from micro-component source wafer 10 by contacting stamp post 34 to micro-component 20 to adhere stamp post 34 to micro-component 20 and moving stamp 30 in a vertical motion in direction Z away from micro-component source wafer 10 and fracture or separate tether 22.

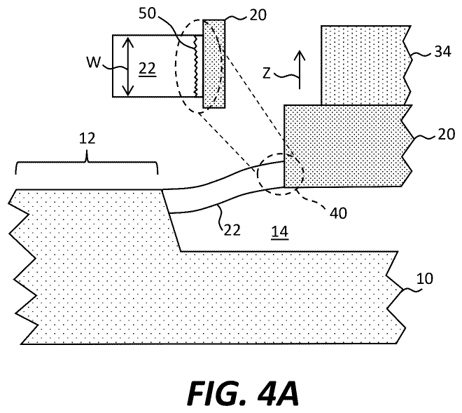

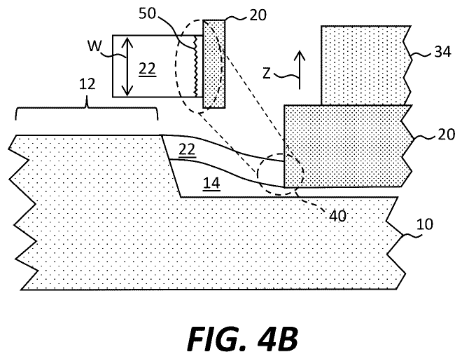

In both FIGS. 3A and 3B, a detail 40 is indicated with a dashed oval that is further illustrated in FIGS. 4-9C to explicate embodiments of the present disclosure.

As shown in the cross sections of FIGS. 4A and 4B, stamp 30 movement in vertical direction Z results in tether 22 deformation so that the end of tether 22 connected to micro-component 20 is no longer in a common plane with the end of tether 22 connected to anchor 12. This movement stresses tether 22 so that it fractures or separates, enabling the removal of micro-component 20 from micro-component source wafer 10. The plan (top) view detail of tether 22 shows that, subject to manufacturing and material variability, the vertical movement of micro-component 20 provides stress distributed across the width W of tether 22 causing a crack 50 to form across the width W in a top (or bottom) surface of tether 22. (Crack 50 is shown at an arbitrary location across tether 22 and can form at any location in tether 22, for example where the stress is greatest or where a notch (not shown) is patterned in tether 22.) The movement of micro-component 20 can be away from micro-component source wafer 10, as shown in FIG. 4A or toward micro-component source wafer 10, as shown in FIG. 4B. Once tether 22 is fractured or separated, stamp 30 with adhered micro-component 20 can be removed from micro-component source wafer 10, e.g., with either or both vertical and horizontal movements away from micro-component source wafer 10 toward a target substrate.

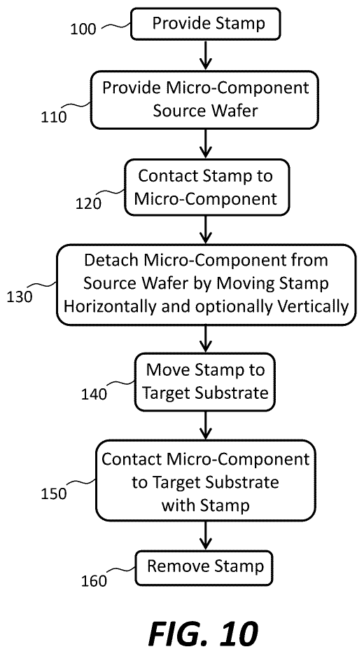

According to embodiments of the present disclosure, in addition to moving stamp 30 and adhered micro-component 20 away from micro-component source wafer 10 in vertical direction Z with a motion-control platform, as shown in FIGS. 3A, 3B, 4A, and 4B (and optionally toward micro-component source wafer 10 in vertical direction Z as shown in FIG. 3A, 4B), the motion-control platform can move stamp 30 in a horizontal direction, for example any one or combination of directions X, Y, and R. Thus, and as further illustrated in FIG. 10, a method of micro-transfer printing can comprise providing a stamp 30 in step 100, providing a micro-component source wafer 10 comprising a micro-component 20 disposed on or over a cavity 14 in a surface of micro-component source wafer 10 connected to micro-component source wafer 10 with a tether 22 in step 110, contacting stamp 30 (e.g., stamp post 34) to micro-component 20 to adhere micro-component 20 to stamp 30 in step 120, and detaching micro-component 20 from micro-component source wafer 10 in step 130 by moving stamp 30 at least partially in a direction parallel to micro-component source wafer 10 (e.g., least partially in a horizontal direction comprising any one or more of directions X, Y, and R substantially parallel to the surface of micro-component source wafer 10 on or over which micro-component 20 is disposed) and optionally in a direction orthogonal to a surface of micro-component source wafer 10 (e.g., direction Z) to fracture or separate tether 22. After detaching micro-component 20 from micro-component source wafer 10 by fracturing or separating tether 22, micro-component 20 can be removed from micro-component source wafer 10 by moving stamp 30 in vertical and horizontal directions. Diagonal movements can be at least partially in two orthogonal directions.

In some embodiments, the horizontal motion of stamp 30 occurs at the same time as vertical motion in direction Z. In some embodiments, the horizontal motion of stamp 30 occurs before vertical motion in direction Z. In some embodiments, the horizontal motion of stamp 30 occurs after vertical motion in direction Z. In some embodiments, stamp 30 is moved in one or more and in any order or combination of vertical and horizontal movements at the same or alternating times. The vertical direction Z can be toward micro-component source wafer 10 or away from micro-component source wafer 10. Micro-component 20 can be detached (e.g., tether 22 can be fractured or separated) from micro-component source wafer 10 with any one or combination of horizontal and vertical movements by stamp 30, including moving stamp 30 in only a horizontal direction. By moving stamp 30 with the motion-control platform, stamp 20 presses (e.g., forces or pushes or pulls) micro-component 20 adhered to stamp post 34, causing micro-component 20 to move, thereby fracturing or separating tether 22 and detaching micro-component 20 from anchor 12 and micro-component source wafer 10. Micro-component 20 is then removed from micro-component source wafer 10 with a stamp 30 vertical motion away from micro-component source wafer 10 and can move horizontally to a target substrate to print micro-component 20 on the target substrate.

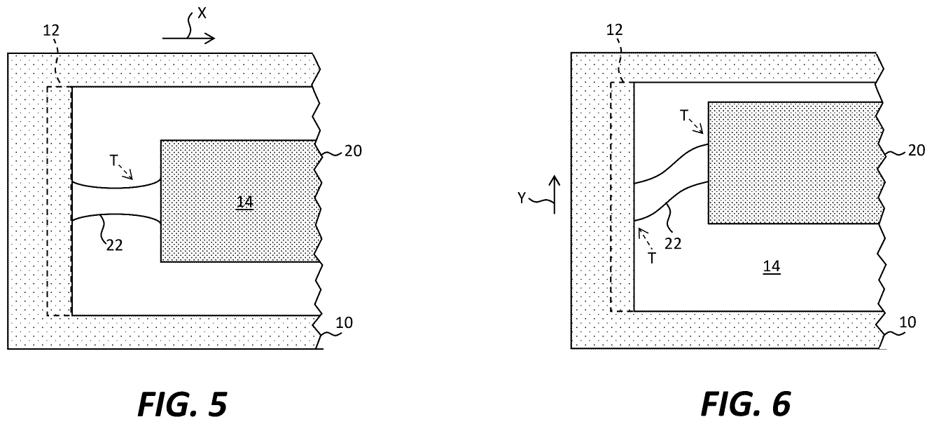

In embodiments of the present disclosure, the horizontal movement of stamp 30 can be any one or combination of movements in directions X, Y, and R and can result in stress to tether 22 to more readily fracture tether 22 and enable micro-component 20 removal from micro-component source wafer 10. The stress can be additional to any stress provided by a simultaneous movement in vertical direction Z. As shown in FIGS. 5-8 and according to embodiments of the present disclosure, by moving stamp 30 in a horizontal direction X, Y, R in addition to a vertical direction Z, stress formed in tether 22 is concentrated over a smaller area or line (e.g., substantially at a point or across a thickness smaller than width W of tether 22, increasing the likelihood and ease of tether 22 fracture or separation. The fracture or separation can then propagate across and through tether 22. The result is that micro-component 20 is more readily removed from micro-component source wafer 10 with less force and requiring less adhesion between micro-component 20 and stamp post 34. In some embodiments, tether 22 is fractured or separated as a result of motion in only one or more of horizontal directions X, Y, and R, so that micro-component 20 is detached from micro-component source wafer 10.

FIG. 5 illustrates the effect of moving stamp 30 with adhered micro-component 20 in a horizontal tether direction X away from anchor 12 (corresponding to the structure shown in FIG. 3A) toward micro-component 20 to translate micro-component 20 over the surface (e.g., move horizontally from one position or location to another different position or location over the surface in direction X). This motion places tether 22 under tension (indicated with a dashed arrow indicating tension T) and stretches tether 22, increasing the stress in tether 22 and increasing the likelihood of fracturing or separating tether 22. FIG. 6 illustrates the effect of moving stamp 30 with adhered micro-component 20 in a horizontal direction Y orthogonal to the tether direction (also corresponding to the structure shown in FIG. 3A). This motion places tether 22 under tension and creates stress in tether 22, particularly where tether 22 is connected to micro-component 20 in the leading edge of tether 22 or where tether 22 is connected to anchor 12 in the trailing edge of tether 22, shown with the dashed arrow indicating tension T, thereby increasing the stress in tether 22 and increasing the likelihood of fracturing or separating tether 22. With respect to bottom tethers 22 as shown in FIG. 3B, stamp 30 and micro-component 20 motion in either X direction or Y direction, or both, can provide similar effects in creating tension in tether 22 and facilitating tether 22 fracture or separation from micro-component 20.

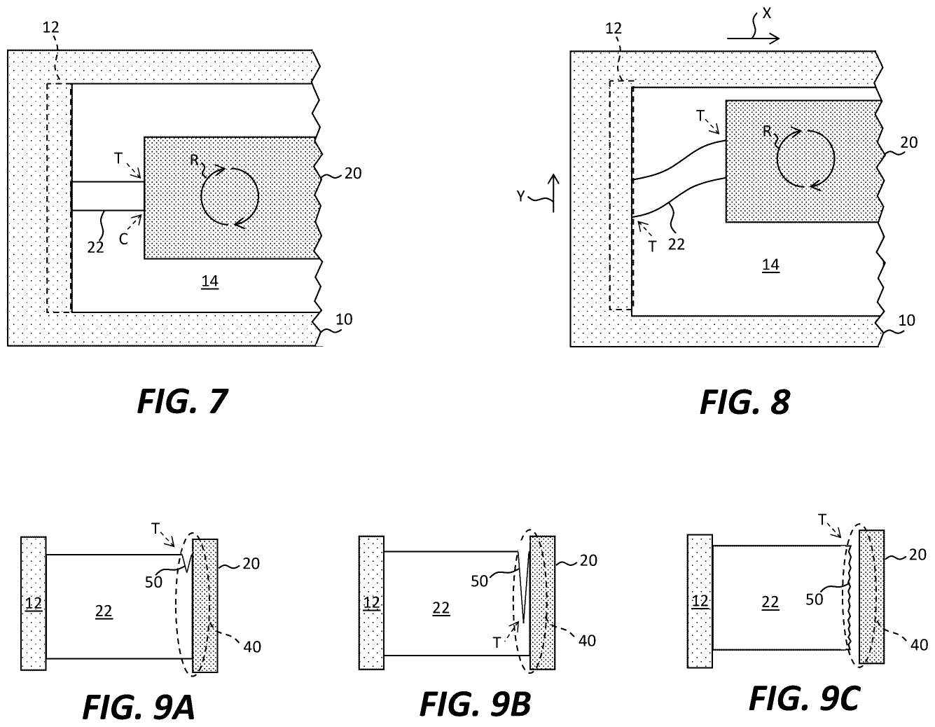

FIG. 7 illustrates the effect of moving stamp 30 with adhered micro-component 20 in a horizontal rotating direction R (corresponding to the structure shown in FIG. 3A) about an axis in direction Z orthogonal to the surface. This motion places tether 22 under tension T on one side of tether 22 (indicated with a dashed arrow) and compresses tether 22 on an opposite side of tether 22 as indicated with compression C, increasing the stress in tether 22 and increasing the likelihood of fracturing or separating tether 22 at the location of tether 22 under tension T. Any of the stamp 30 and micro-component 20 motions in directions X, Y, and R of FIGS. 5-7 can be combined, as shown in FIG. 8, to provide additional stress concentrated at specific locations in tether 22, for example where tension T in tether 22 is increased, increasing the likelihood of fracture and separation and reducing the force needed and adhesion required between micro-component 20 and stamp post 34 to remove micro-component 20 from micro-component source wafer 10, thus increasing micro-transfer printing pick yields in a micro-component 20 micro-transfer printing micro-assembly process. Any or all of the horizontal directions X, Y, and R can be combined with stamp 30 vertical motion in direction Z to enable micro-transfer printing with increased yields, reliability, and robustness under variable conditions (e.g., micro-component 20 types, materials, sizes, and shapes).

FIGS. 9A-9C illustrate the effects of concentrating force due to stamp 30 and micro-component 20 motion on a specific location or portion of tether 22, indicated with T. As shown in FIG. 9A, an initial crack 50 is formed at a vertical edge (or a point at a corner) of tether 22 due to tension in tether 22 produced by stamp 30 and micro-component 20 motion. As the motion continues, crack 50 propagates across tether 22, as shown in FIG. 9B, culminating in a crack 50 extending all the way across tether 22, thereby fracturing (breaking) or separating tether 22. Tether 22 is a three-dimensional structure, albeit relatively thin compared to its width W or length in a direction orthogonal to width W. By moving stamp 30 and micro-component 20 both vertically and horizontally, force can be concentrated at a side (e.g., a relatively thin vertical side) or point (e.g., a corner) of tether 22 rather than across a surface of tether 22, thereby more readily starting or forming crack 50 in tether 22 with an equivalent force.

In all of FIGS. 4-9C, movement and sizes are exaggerated to illustrate and clarify embodiments of the present disclosure. In practice, any motion can be, for example, no greater than twenty, ten, five, two, or one micron to detach micro-component 20 from anchor 12 of micro-component source wafer 10.

As shown further in FIG. 10, once micro-component 20 is detached from micro-component source wafer 10 in step 130 using a motion-control platform, stamp 30 and adhered micro-component 20 can be removed to a target substrate in step 140, micro-component 20 can be contacted to the target substrate to adhere micro-component 20 to the target substrate in step 150, and stamp 30 removed from the target substrate in step 160, thereby micro-transfer printing micro-component 20 from micro-component source wafer 10 to the target substrate.

Micro-component 20 can, for example, have a thickness no greater than 250 μm (e.g., no greater than 200 μm, no greater than 150 μm, no greater than 100 μm, no greater than 75 μm, no greater than 50 μm, no greater than 25 μm, no greater than 10 μm, no greater than 5 μm, no greater than 3 μm, or no greater than 2 μm). Similarly, micro-component 20 can have an area no greater than 100,000 μm² (e.g., no greater than 62,500 μm², less than 62,500 μm², no greater than 40,000 μm², less than 40,000 μm², no greater than 20,000 μm², no greater than 10,000 μm², no greater than 2,500 μm², no greater than 400 μm², no greater than 100 μm², no greater than 50 μm², or no greater than 20 μm²). Micro-component 20 can have a width of no greater than 100 μm, 50 μm, 20 μm, or 10 μm and a length of no greater than 10 μm, 20 μm, 50 μm, 100 μm, 200 μm, 250 μm, or 500 μm. Micro-component 10 can have a width and a length both no greater than 500 μm, 250 μm, 100 μm, 50 μm, 20 μm, 10 μm, or 5 μm. Micro-component 20 can be substantially square or rectangular or can have a large aspect ratio (length to width), for example no less than 2:1, no less than 4:1, no less than 5:1, no less than 8:1, or no less than 10:1.

In some embodiments, micro-component 20 is attached to micro-component source wafer 10 with multiple tethers 22, each tether 22 connected to an anchor 12.

As used herein, a device (e.g., micro-component 20) native to a substrate (e.g., micro-component source wafer 10) is formed on the substrate, for example by photolithographically processing and patterning layers of material that were directly deposited on the substrate, for example by sputtering or vapor deposition. A device (e.g., micro-component 20) formed on a native substrate (e.g., micro-component source wafer 10) and then transferred to a second substrate (e.g., a target substrate) is non-native to the second substrate.

Examples of micro-transfer printing processes suitable for printing components onto target substrates are described in U.S. Pat. No. 8,722,458 entitled Optical Systems Fabricated by Printing-Based Assembly, U.S. Pat. No. 9,362,113 entitled Engineered Substrates for Semiconductor Epitaxy and Methods of Fabricating the Same, U.S. Pat. No. 9,358,775 entitled Apparatus and Methods for Micro-Transfer-Printing, U.S. patent application Ser. No. 14/822,868, filed on Aug. 10, 2015, entitled Compound Micro-Assembly Strategies and Devices, and U.S. Pat. No. 9,704,821 entitled Stamp with Structured Posts, each of which is hereby incorporated by reference herein in its entirety.

The terms horizontal and vertical are arbitrary labels and can be exchanged. Similarly, the terms x direction, y direction, and z direction are arbitrarily labeled and can be exchanged. A horizontal direction X can be exchanged with a horizontal direction Y.

It is contemplated that systems, devices, methods, and processes of the disclosure encompass variations and adaptations developed using information from the embodiments described herein. Adaptation and/or modification of the systems, devices, methods, and processes described herein may be performed by those of ordinary skill in the relevant art.

Throughout the description, where articles, devices, and systems are described as having, including, or comprising specific components, or where processes and methods are described as having, including, or comprising specific steps, it is contemplated that, additionally, there are articles, devices, and systems according to certain embodiments of the present disclosure that consist essentially of, or consist of, the recited components, and that there are processes and methods according to certain embodiments of the present disclosure that consist essentially of, or consist of, the recited processing steps.

It should be understood that the order of steps or order for performing certain actions is immaterial so long as operability is not lost. Moreover, two or more steps or actions may be conducted simultaneously.

Certain embodiments of the present disclosure were described above. It is, however, expressly noted that the present disclosure is not limited to those embodiments, but rather the intention is that additions and modifications to what was expressly described in the present disclosure are also included within the scope of the disclosure. Moreover, it is to be understood that the features of the various embodiments described in the present disclosure were not mutually exclusive and can exist in various combinations and permutations, even if such combinations or permutations were not made express, without departing from the spirit and scope of the disclosure. Having described certain implementations of heterogeneous wafer structures, heterogeneous semiconductor structures, methods of their fabrication, and methods of their use, it will now become apparent to one of skill in the art that other implementations incorporating the concepts of the disclosure may be used. Therefore, the disclosure should not be limited to certain implementations, but rather should be limited only by the spirit and scope of the following claims.

### PARTS LIST

C compression
X x direction
R rotation direction
T tension
W width
X direction
Y direction
Z direction
10 micro-component source wafer/source substrate
12 anchor/anchor portion
14 cavity
16 surface
20 micro-component
22 tether
30 stamp
32 rigid back
34 stamp post
36 stamp pedestal
40 detail
50 crack
100 provide stamp step
110 provide micro-component source wafer step
120 contact stamp to micro-component step
130 detach micro-component from source wafer by moving stamp horizontally and vertically step
140 move stamp to target substrate step
150 contact micro-component to target substrate step
160 remove stamp step

What is claimed is:

1. A method of micro-transfer printing, comprising:
providing a stamp;
providing a micro-component source wafer comprising a micro-component disposed over a cavity in a surface of the micro-component source wafer and connected to the micro-component source wafer with a tether;
contacting the stamp to the micro-component to adhere the micro-component to the stamp; and
detaching the micro-component from the micro-component source wafer by moving the stamp, wherein the moving comprises moving the stamp in a horizontal direction parallel to the surface.

2. The method of claim 1, wherein the moving comprises moving the stamp in a vertical direction orthogonal to the surface before moving the stamp in the horizontal direction.

3. The method of claim 2, wherein moving the stamp in the vertical direction comprises moving the stamp toward the surface.

4. The method of claim 1, wherein the moving comprises moving the stamp in a vertical direction orthogonal to the surface at a same time as moving the stamp in the horizontal direction.

5. The method of claim 4, wherein moving the stamp in the vertical direction comprises moving the stamp toward the surface.

6. The method of claim 1, wherein the moving comprises moving the stamp in a vertical direction orthogonal to the surface after moving the stamp in the horizontal direction.

7. The method of claim 6, wherein moving the stamp in the vertical direction comprises moving the stamp toward the surface.

8. The method of claim 1, wherein moving the stamp in the vertical direction comprises moving the stamp away from the surface.

9. The method of claim 1, wherein moving the stamp in the horizontal direction comprises a rotation of the stamp about a vertical axis extending in a vertical direction orthogonal to the surface.

10. The method of claim 1, wherein the tether extends horizontally in a tether direction away from an anchor portion of the micro-component source wafer toward the micro-component and moving the stamp comprises moving the stamp in the tether direction to stretch the tether.

11. The method of claim 1, wherein the tether extends horizontally in a tether direction away from an anchor portion of the micro-component source wafer toward the micro-component and moving the stamp in the horizontal direction comprises moving the stamp orthogonal to the tether direction.

12. The method of claim 1, wherein the tether extends in a tether direction away from an anchor of the micro-component source wafer toward the micro-component and the horizontal direction parallel to the surface is orthogonal to the tether direction and moving the stamp in the horizontal direction comprises a rotation about a vertical axis extending in the vertical direction that stretches a leading edge of the tether moving in the orthogonal direction and compresses a trailing edge of the tether.

13. The method of claim 1, wherein moving the stamp in the horizontal direction comprises rotating the stamp about a vertical axis extending in a vertical direction orthogonal to the surface and a horizontal translation of the micro-component over the surface.

14. The method of claim 1, wherein the tether extends laterally from an edge of the micro-component to an anchor portion of the micro-component source wafer.

15. The method of claim 1, wherein the tether extends from a bottom of the micro-component to the micro-component source wafer.

16. The method of claim 1, wherein the stamp comprises a rigid back and a stamp post extending away from the rigid substrate and wherein a distal end of the stamp post contacts the micro-component.

17. The method of claim 16, wherein the stamp comprises a pedestal disposed on the rigid back or on a bulk layer on the rigid back and a proximal end of the post is in contact with the pedestal or bulk layer.

18. A structure for micro-transfer printing, comprising:
a micro-component source wafer comprising a micro-component disposed over a cavity in a surface of the micro-component source wafer and connected to an anchor portion of the micro-component source wafer with a tether that extends from the anchor to the micro-component; and
a stamp disposed in contact with the micro-component adhering the micro-component to the stamp,
wherein the stamp is providing force to the micro-component in a horizontal direction parallel to the surface.

19. The structure for micro-transfer printing of claim 18, wherein the stamp is also providing force to the micro-component in a vertical direction orthogonal to the surface.

20. The structure for micro-transfer printing of claim 18, wherein at least a portion of the tether is under tension in the horizontal direction.

21. The structure for micro-transfer printing of claim 18, wherein the force in the horizontal direction is a rotational force.

22. The structure for micro-transfer printing of claim 18, wherein the force in the horizontal direction is in a direction in which the tether extends.

23. The structure for micro-transfer printing of claim 18, wherein the force in the horizontal direction is orthogonal to a direction in which the tether extends.

24. The structure for micro-transfer printing of claim 18, wherein the force in the horizontal direction is two or more of (i) a force in a direction orthogonal to a direction from the anchor to the micro-component, (ii) a force in a direction from the anchor to the micro-component, and (iii) a rotational force about a vertical axis extending in the vertical direction.

25. A method of micro-transfer printing, comprising:
providing a micro-component source wafer comprising a micro-component disposed over a cavity in a surface of the micro-component source wafer and connected to the micro-component source wafer; and
detaching the micro-component from the micro-component source wafer by moving the micro-component at least in a horizontal direction parallel to the surface.

26. The method of claim 25, wherein the micro-component is connected to the micro component source wafer with a tether and detaching the micro-component from the micro-component source wafer fractures or separates the tether.
